(19) United States
(12) Patent Application Publication
(10) Pub. No.: US 2025/0329699 A1
(43) Pub. Date: Oct. 23, 2025

(54) SEMICONDUCTOR MODULE AND SEMICONDUCTOR PACKAGE

(71) Applicant: UltraMemory Inc., Tokyo (JP)

(72) Inventor: Fumitake OKUTSU, Tokyo (JP)

(21) Appl. No.: 18/716,628

(22) PCT Filed: Dec. 10, 2021
(86) PCT No.: PCT/JP2021/045599

§ 371 Date: Jun. 5, 2024

(51) Int. Cl. H01L 25/18; H01L 23/00; H01L 23/31; H01L 25/065; H10B 80/00; H10D 80/30

(52) U.S. Cl. CPC H01L 25/18; H01L 23/3128; H01L 23/3185; H01L 24/08; H01L 24/16; H01L 25/0657; H10B 80/00; H10D 80/30; H01L 2224/08145; H01L 2224/16145; H01L 2224/16225; H01L 2225/06513; H01L 2225/06517; H01L 2225/06562; H01L 2924/1431; H01L 2924/1436

(57) ABSTRACT

A semiconductor module includes: a reference panel, which includes a plurality of reference chips arranged in a row and a reference molded section that fills at least spaces between the plurality of reference chips; and a layered panel which comprises layered chips layered respectively onto the reference chips, and a layered molded section that fills at least spaces between the plurality of layered chips, the layered panel being layered onto one side of the reference panel. Each of the layered chips is disposed so that a partial region thereof overlaps with a partial region of the respective reference chip in a layering direction and is disposed so as to overlap with the reference molded section. The reference chips are disposed so as to overlap with the layered molded section.

### TECHNICAL FIELD

The present invention relates to a semiconductor module and a semiconductor package.

### BACKGROUND ART

Conventionally, a volatile memory (RAM) such as a dynamic random access memory (DRAM) is known as a storage device. The DRAM is required to have a large capacity capable of withstanding high performance of an arithmetic device (hereinafter referred to as a logic chip) and an increase in the amount of data. Therefore, efforts have been made to increase capacity by miniaturizing memories (memory cell arrays, memory chips) and expanding cells in a planar manner. On the other hand, this type of increase in capacity has reached a limit due to the susceptibility to noise due to miniaturization, increased chip area, and the like.

Therefore, recently, a technique has been developed in which a plurality of planar memories are stacked to be three-dimensional (3D) to realize a large capacity. As the amount of data increases, the speed of data communication between chips (logic chips and memory chips) is increased (see Patent Documents 1 and 2, for example).

### CITATION LIST

### Patent Document

Patent Document 1: US Patent Application, Publication No. 2016/0300813

Patent Document 2: Chinese Patent Application, Publication No. 103887279

### DISCLOSURE OF THE INVENTION

### Problems to be Solved by the Invention

With regard to the package of Patent Document 1, dies are mounted on front and back sides of a redistribution layer (RDL). In Patent Document 1, a first molding compound encapsulates the die on the front side of the RDL. In Patent Document 1, a second molding compound encapsulates the other die on the back side of the RDL. In Patent Document 1, package warpage is suppressed by controlling the thicknesses of the two dies, the first molding compound, and the second molding compound. However, when shrinkage stresses of the first molding compound and the second molding compound accumulate, warpage may occur over the entire wafer before singulation into packages.

With regard to the package of Patent Document 2, each of two stacked packages includes a chip and a metal layer disposed in the vicinity of a side surface of the chip. In Patent Document 2, the chip and the metal layer are molded using a first mold body and a second mold body disposed in the vicinity of the side surface of the chip. In Patent Document 2, warpage of the entire wafer is suppressed by providing the metal layer. However, placing the metal layer may increase manufacturing steps. Further, placing the metal layer may also increase the manufacturing cost.

In response to the above issues, an object of the present invention is to provide a semiconductor module and a semiconductor package for which warpage before singulation can be easily suppressed.

### Means for Solving the Problems

The present invention relates to a semiconductor module formed by integrally molding a plurality of chips. The semiconductor module includes a reference panel including a plurality of reference chips arranged side by side, and a reference mold portion that fills at least spaces between the plurality of reference chips; and at least one stacked panel including a plurality of stacked chips respectively stacked on the reference chips, and a stacked mold portion that fills at least spaces between the plurality of stacked chips, the stacked panel being stacked on one surface side of the reference panel. Each of the stacked chips is disposed so that a partial area thereof overlaps a partial area of a corresponding reference chip when viewed in a stacking direction and is disposed so as to overlap the reference mold portion. The reference chips are disposed so as to overlap the stacked mold portion.

It is preferable that the stacked chips are stacked in a one-to-one correspondence with the reference chips in the stacking direction.

It is preferable that each of the reference chips is disposed toward one end of one diagonal line in a predetermined area of a rectangle in plan view including one of the reference chips and one of the stacked chips, in a direction intersecting the stacking direction, and that each of the stacked chips is disposed toward the other end of the one diagonal line.

The at least one stacked panel preferably includes a plurality of stacked panels. It is preferable that each of the stacked chips is disposed so as to partially overlap an other adjacent stacked chip when viewed in the staking direction and overlap the stacked mold portion of the other adjacent stacked chip.

It is preferable that the stacked chips are stacked in a one-to-one correspondence with the other stacked chips in the stacking direction.

The other stacked chip is preferably disposed toward one end of the other diagonal line. Still another stacked chip is preferably disposed toward the other end of the other diagonal line.

The stacked chips are preferably different types of chips for each of the stacked panels.

Preferably, at least one of the stacked chips is a bumpless stacked chip.

The stacked panel is preferably connected to another stacked panel or the reference panel using microbumps.

Preferably, the reference chips are chips of a different type from the stacked chips.

Further, the present invention relates to a semiconductor package obtained by singulating the above semiconductor module. The semiconductor package includes one of the reference chips and corresponding stacked chip that are disposed so as to overlap each other as a set.

### Effects of the Invention

According to the present invention, it is possible to provide a semiconductor module and a semiconductor package for which warpage before singulation can be easily suppressed.

### BRIEF DESCRIPTION OF THE DRAWINGS

FIG. 1 is a plan view showing a semiconductor module according to a first embodiment of the present invention;

FIG. 2 is a partially enlarged view of FIG. 1;

FIG. 3 is a sectional view taken along line A-A of FIG. 2;

FIG. 4 is a plan view showing a semiconductor package obtained by singulating the semiconductor module of the first embodiment;

FIG. 5 is a sectional view taken along line B-B of FIG. 4;

FIG. 6 is a plan view showing a semiconductor module according to a second embodiment of the present invention;

FIG. 7 is a partially enlarged view of FIG. 6;

FIG. 8 is a sectional view taken along line C-C of FIG. 7;

FIG. 9 is a sectional view of a semiconductor package obtained by singulating the semiconductor module of the second embodiment;

FIG. 10 is a plan view showing a semiconductor package obtained by singulating a semiconductor module according to a third embodiment of the present invention; and

FIG. 11 is a sectional view of another semiconductor package according to the third embodiment.

### PREFERRED MODE FOR CARRYING OUT THE INVENTION

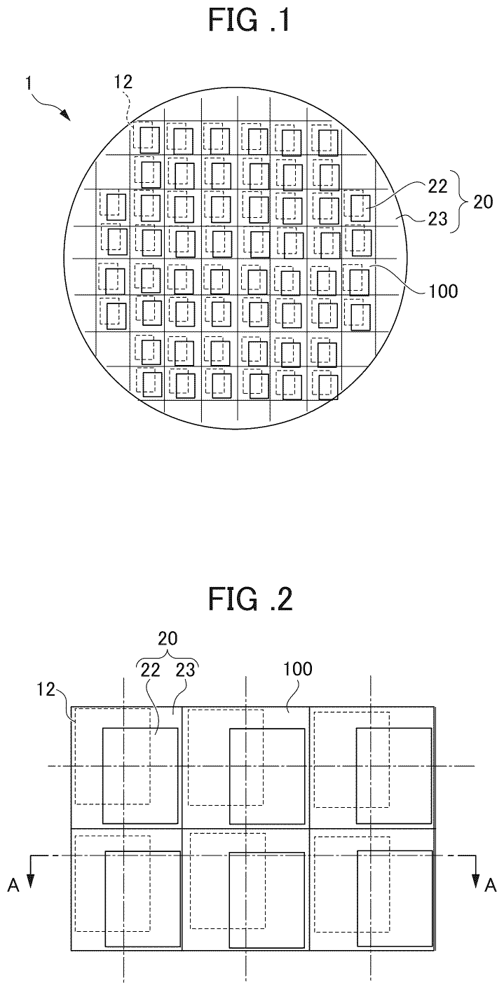

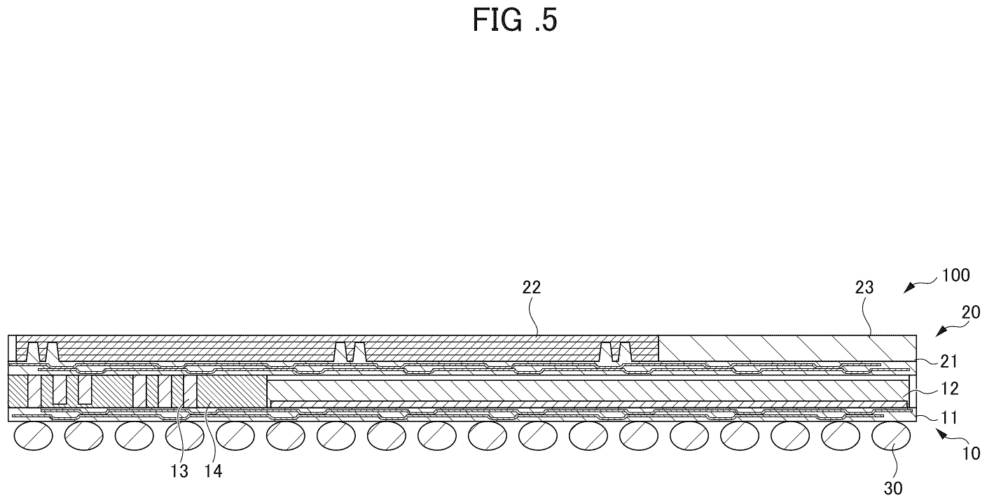

Hereinafter, a semiconductor module 1 and a semiconductor package 100 according to each embodiment of the present invention will be described with reference to FIGS. 1 to 11. First, an outline of the semiconductor module 1 and the semiconductor package 100 according to each embodiment will be described.

In the semiconductor module 1 according to each embodiment, a plurality of semiconductor panels each including a plurality of chips arranged side by side are stacked, so that a plurality of chips are stacked in the stacking direction. The semiconductor module 1 and the semiconductor panel may have a circular wafer shape as shown in FIG. 1 or a rectangular plate shape (not shown). The semiconductor panel has a structure in which a mold member fills at least between the plurality of chips arranged side by side. Here, a difference in shrinkage stress due to a difference in thermal expansion coefficients occurs between the mold member and the chip. Therefore, shrinkage stress accumulates at the overlapping positions of the mold members. Warpage may occur in the semiconductor module 1 due to accumulation of shrinkage stress. In each of the following embodiments, the accumulation of shrinkage stress is suppressed by shifting the positions of the chips to be stacked in a direction intersecting the stacking direction.

### First Embodiment

Next, a semiconductor module 1 and a semiconductor package 100 according to a first embodiment of the present invention will be described with reference to FIGS. 1 to 5. As shown in FIGS. 1 to 3, the semiconductor module 1 is formed by integrally molding a plurality of chips. The semiconductor module 1 includes a reference panel 10, a stacked panel 20, and external connection bumps 30.

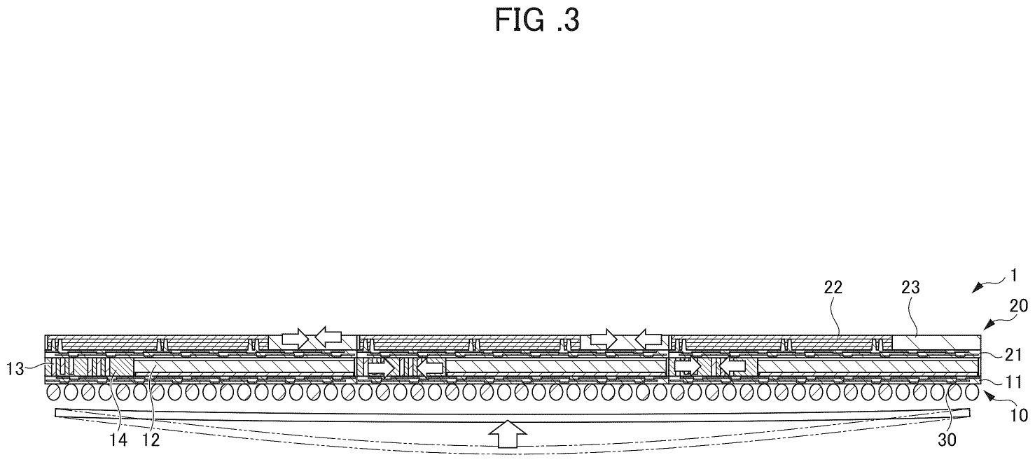

The reference panel 10 is, for example, a semiconductor panel formed in a circular shape in plan view. The reference panel 10 has, for example, a structure in which a plurality of chips are arranged side by side and a mold member fills at least between the chips. As shown in FIG. 3, the reference panel 10 includes a reference redistribution layer (RDL) 11, a reference chip 12, a pillar 13, and a reference mold portion 14.

The reference RDL 11 has, for example, a circular shape in plan view. The reference RDL 11 enables electrical connection in the thickness direction (stacking direction), for example. As shown in FIG. 3, the reference RDL 11 forms a surface exposed on one plane of the reference panel 10.

The reference chip 12 is a chip of a different type from the stacked chips described later. The reference chip 12 is, for example, a logic chip. As shown in FIGS. 1 and 2, a plurality of reference chips 12 are provided and arranged side by side. In the present embodiment, the reference chips 12 each have a rectangular shape in plan view and are arranged in a grid pattern. The plurality of reference chips 12 are arranged on one surface of the reference RDL 11 and electrically connected to the reference RDL 11.

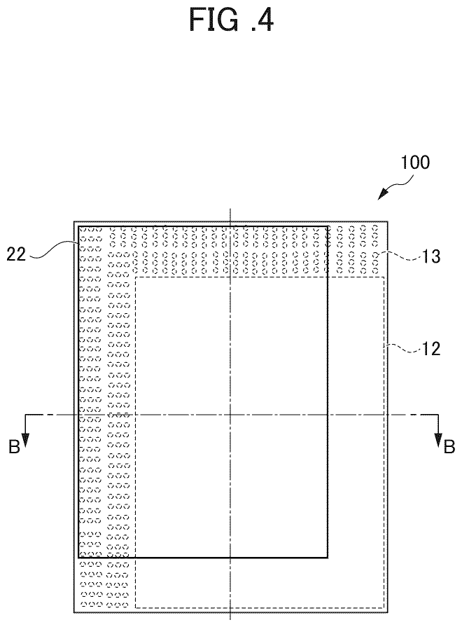

The pillar 13 is Cu, for example. The pillar 13 extends from one surface of the reference RDL 11. The pillar 13 is, for example, configured to have the same height or substantially the same height as the height of the logic chip in the stacking direction. As shown in FIGS. 3 and 4, a plurality of pillars 13 are provided, for example.

The reference mold portion 14 fills at least spaces between the plurality of reference chips 12. The reference mold portion 14 is, for example, a thermosetting epoxy resin or the like. As shown in FIGS. 1 to 3, the outer shape of the reference mold portion 14 is formed in accordance with the circular shape of the reference RDL 11 in plan view, for example,

The stacked panel 20 is, for example, a semiconductor panel formed in a circular shape in plan view having the same diameter as that of the reference panel 10. The stacked panel 20 has a structure in which a plurality of chips are arranged side by side and a mold member fills at least between the chips, for example. As shown in FIG. 3, the stacked panel 20 includes a stacked RDL 21, a stacked chip 22, and a stacked mold portion 23. As shown in FIG. 3, the stacked panel 20 is stacked on one surface side of the reference panel 10. Specifically, the stacked panel 20 is stacked on a surface of the reference panel 10 opposite to the surface where the reference RDL 11 is exposed.

The stacked RDL 21 is formed in a circular shape in plan view, for example. The stacked RDL 21 enables electrical connection in the thickness direction (stacking direction), for example. The stacked RDL 21 forms a surface exposed on one plane of the stacked panel 20. In the present embodiment, the stacked RDL 21 may be disposed in contact with the reference chip 12 and the reference mold portion 14 exposed on the other surface of the reference panel 10. The stacked RDL 21 is electrically connected to the pillar 13.

The stacked chip 22 is, for example, a RAM. As shown in FIGS. 1 and 2, a plurality of stacked chips 22 are provided and arranged side by side. In the present embodiment, the stacked chips 22 are rectangular in plan view and arranged in a grid pattern. The plurality of stacked chips 22 are arranged on one surface of the stacked RDL 21 and electrically connected to the stacked RDL 21.

The stacked mold portion 23 fills at least spaces between the plurality of stacked chips 22. The stacked mold portion 23 is, for example, a thermosetting epoxy resin or the like. As shown in FIGS. 1 to 3, the outer shape of the stacked mold portion 23 is formed in accordance with the circular shape of the stacked RDL 21 in plan view, for example.

According to the reference chip 12, the stacked chip 22, the reference mold portion 14, and the stacked mold portion 23 described above, as shown in FIGS. 1 to 5, the stacked chip 22 is disposed so that a partial area thereof overlaps a partial area of the reference chip 12 when viewed in the stacking direction. The reference chip 12 is disposed so as to overlap the stacked mold portion 23. The stacked chips 22 are stacked in a one-to-one correspondence with the reference chips 12 in the stacking direction. Here, the reference chip 12 is disposed toward one end of one diagonal line in a predetermined area of a rectangle in plan view including the reference chip 12 and the stacked chip 22 in a direction intersecting the stacking direction. The stacked chip 22 is disposed toward the other end of one diagonal line. That is, as shown in FIGS. 1, 2, and 4, the reference chip 12 and the stacked chip 22 are disposed so as to be offset in one diagonal direction of the rectangular area and in a direction away from each other (each toward the corner). That is, the reference chip 12 is disposed so as to overlap both the stacked mold portion 23 and the stacked chip 22 in the direction intersecting the stacking direction. The stacked chip 22 is disposed so as to overlap both the reference mold portion 14 and the reference chip 12 in the direction intersecting the stacking direction. In this manner, the reference chip 12 and the stacked chip 22 are disposed in the stacking direction so as to reduce the overlapping area between the reference mold portion 14 and the stacked mold portion 23.

The semiconductor package 100 is obtained by singulation to obtain the reference chip 12 and the stacked chip 22, which are disposed to overlap each other, as a set. Specifically, as shown in FIG. 2, the semiconductor package 100 can be obtained by singulating the semiconductor module 1 for each predetermined rectangular area including one reference chip 12 and one stacked chip 22.

The external connection bump 30 is, for example, a solder bump. The external connection bump 30 is arranged to establish an electrical connection with the outside of the semiconductor module 1 (semiconductor package 100). The external connection bump 30 is arranged on the exposed surface of the reference RDL 11.

Next, the semiconductor module 1 of the present embodiment and the operation of the semiconductor module 1 will be described. By applying heat when the reference panel 10 and the stacked panel 20 are stacked, the reference mold portion 14 and the stacked mold portion 23 shrink. As shown in FIG. 3, when viewed in the stacking direction, the stacked chip 22 having a small shrinkage stress overlaps the reference mold portion 14 having a large shrinkage stress. Further, the reference chip 12 having a small shrinkage stress overlaps the stacked mold portion 23 having a large shrinkage stress. Accordingly, concentration of shrinkage stress can be suppressed compared to the case where the reference mold portion 14 and the stacked mold portion 23 overlap each other. Therefore, warpage of the semiconductor module 1 is reduced compared to the case where the reference mold portion 14 and the stacked mold portion 23, both of which have large shrinkage stresses, are disposed to overlap each other.

The semiconductor module 1 and the semiconductor package 100 according to the first embodiment as described above achieve the following effects.

(1) A semiconductor module 1 formed by integrally molding a plurality of chips includes a reference panel 10 including a plurality of reference chips 12 arranged side by side, and a reference mold portion 14 that fills at least spaces between the plurality of reference chips 12; and at least one stacked panel 20 including a plurality of stacked chips 22 respectively stacked on the reference chips 12, and a stacked mold portion 23 that fills at least spaces between the plurality of stacked chips 22, the stacked panel 20 being stacked on one surface side of the reference panel 10. Each of the stacked chips 22 is disposed so that a partial area thereof overlaps a partial area of a corresponding reference chip 12 when viewed in a stacking direction and is disposed so as to overlap the reference mold portion 14. The reference chips 12 are disposed so as to overlap the stacked mold portion 23. Accordingly, since the shrinkage stress applied to the semiconductor module 1 can be dispersed, warpage of the semiconductor module 1 before singulation can be easily suppressed.

(2) The stacked chips 22 are stacked in a one-to-one correspondence with the reference chips 12 in the stacking direction. Accordingly, since a chip is not disposed across a plurality of chips in the direction intersecting the stacking direction, it is possible to facilitate singulation.

(3) Each of the reference chips 12 is disposed toward one end of one diagonal line in a predetermined area of a rectangle in plan view including one of the reference chips 12 and one of the stacked chips 22, in a direction intersecting the stacking direction, and each of the stacked chips 22 is disposed toward the other end of the one diagonal line. Accordingly, since the chip and the mold portion overlap each other in a wider area, shrinkage stress can be further dispersed, and thus warpage before singulation can be easily suppressed.

### Second Embodiment

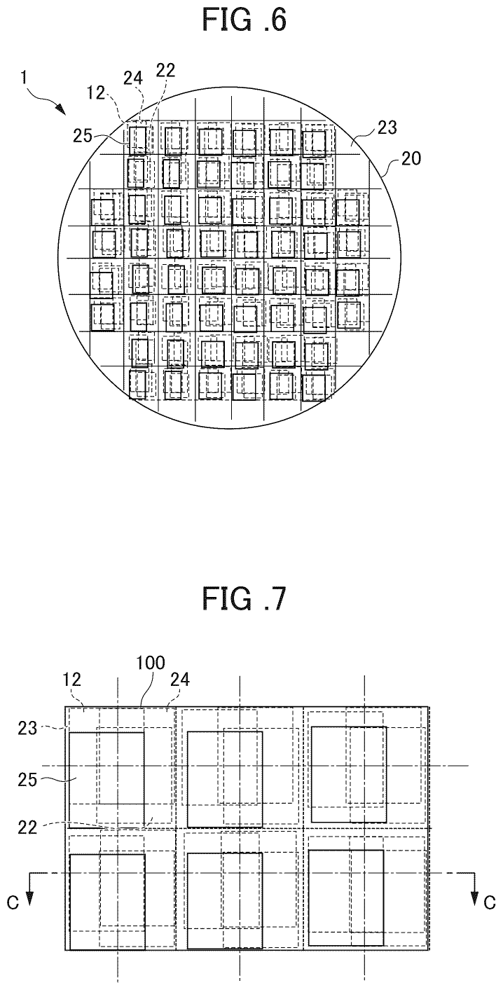

Next, a semiconductor module 1 and a semiconductor package 100 according to a second embodiment of the present invention will be described with reference to FIGS. 6 to 9. In the second embodiment, the same components are denoted by the same reference numerals, and the descriptions thereof are simplified or omitted. As shown in FIGS. 6 to 9, the semiconductor module 1 according to the second embodiment differs from that of the first embodiment in that a plurality of stacked panels 20 are provided. In addition, the semiconductor module 1 according to the second embodiment differs from that of the first embodiment in that a stacked chip 22 is disposed so as to partially overlap an other adjacent stacked chip 22 and is disposed so as to overlap the stacked mold portion 23 of the other adjacent stacked chip 22, when viewed in the stacking direction. The semiconductor module 1 according to the second embodiment differs from that of the first embodiment in that the stacked panel 20 and another stacked panel 20 include pillars 26 similarly to a reference panel 10.

As shown in FIGS. 6 to 9, the stacked chip 22 is stacked in a one-to-one correspondence with an other stacked chip 24 in the stacking direction. Further, the stacked chip 22 is stacked in a one-to-one correspondence with still an other stacked chip 25. That is, the stacked chip 22 is disposed in a one-to-one correspondence with the reference chip 12, the other stacked chip 24, and the still other stacked chip 25.

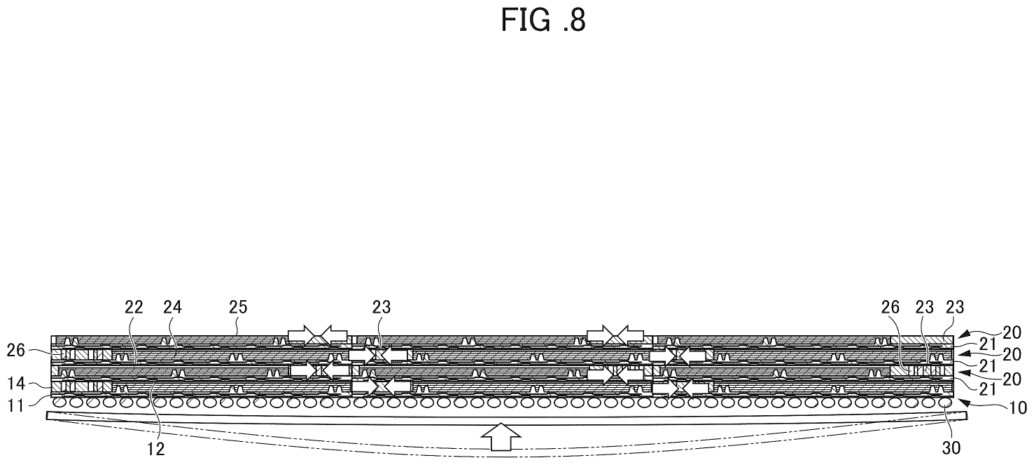

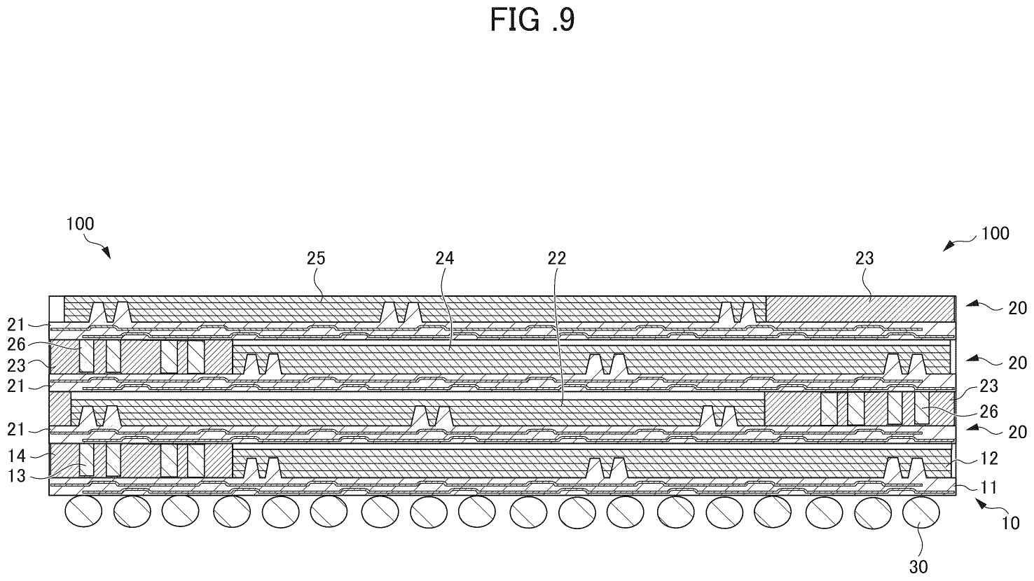

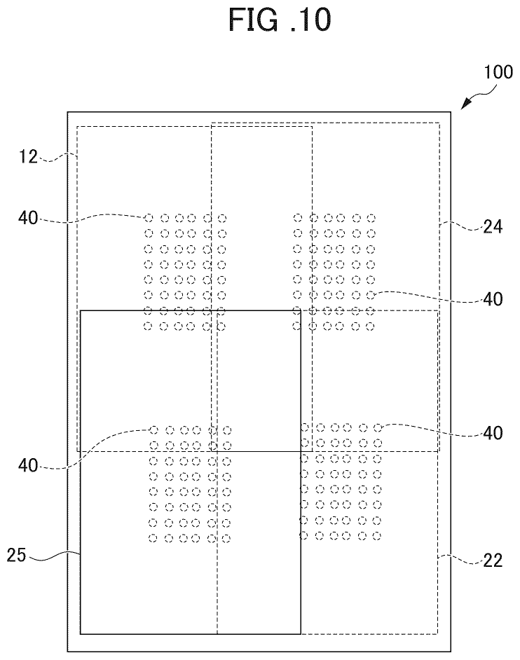

Here, as shown in FIGS. 6 and 7, the other stacked chip 24 and the other stacked chip 25 are disposed on the other diagonal line with respect to one diagonal line of the first embodiment. Specifically, the other stacked chip 24 is disposed toward one end of the other diagonal line. Further, the other stacked chip 25 is disposed toward the other end of the other diagonal line. That is, the reference chip 12, the stacked chip 22, the other stacked chip 24, and the other stacked chip 25 are disposed in the four quadrants of the predetermined area and in the vicinity of the corners of the rectangular area. As a result, as shown in FIGS. 8 and 9, the semiconductor module 1 reduces the area where the reference mold portion 14 and the stacked mold portion 23 overlap each other when viewed in the stacking direction. Therefore, warpage of the semiconductor module 1 is suppressed.

The semiconductor module 1 and the semiconductor package 100 according to the second embodiment as described above achieve the following effects.

(4) The at least one stacked panel 20 includes a plurality of stacked panels 20. Each of the stacked chips 22 is disposed so as to partially overlap an other adjacent stacked chip 24 when viewed in the staking direction and overlap a stacked mold portion 23 of the other adjacent stacked chip 24. Accordingly, since the area where mold portions overlap each other when viewed in the stacking direction can be reduced, warpage of the semiconductor module 1 can be easily suppressed.

(5) The stacked chips 22 are stacked in a one-to-one correspondence with the other stacked chips 24 in the stacking direction. Thus, the semiconductor wafer 1 can be easily singulated.

(6) The other stacked chip 24 is disposed toward one end of the other diagonal line. Still another stacked chip 25 is disposed toward the other end of the other diagonal line. As a result, since the area where mold portions overlap each other when viewed in the stacking direction of the semiconductor module 1 can be further reduced, warpage of the semiconductor module 1 can be suppressed.

### Third Embodiment

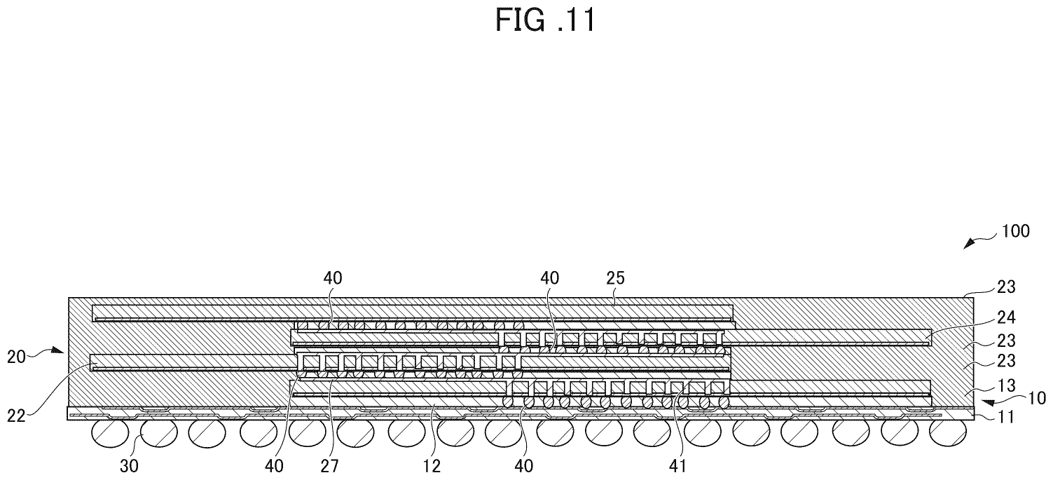

Next, a semiconductor module 1 and a semiconductor package 100 according to a third embodiment of the present invention will be described with reference to FIGS. 10 and 11. In the third embodiment, the same components are denoted by the same reference numerals, and the descriptions thereof are simplified or omitted. The semiconductor module 1 and the semiconductor package 100 according to the third embodiment differ from those of the first and second embodiments in that a reference chip 12 and a stacked chip 22 are connected to each other using microbumps 40, a silicon through electrode 41, and a back surface RDL 27 formed on the surface opposite to a reference RDL 11 in the reference chip 12. That is, as shown in FIG. 11, the semiconductor module 1 and the semiconductor package 100 according to the third embodiment differ from those of the first and second embodiments in that the reference panel 10 and the stacked panel 20 are connected to each other using the microbumps 40, the silicon through electrode 41, and the back surface RDL 27 electrically connected to the silicon through electrode 41. As shown in FIG. 10, the third embodiment differs from the first and second embodiments in that, when in the semiconductor module 1 and the semiconductor package 100 according to the third embodiment, the microbumps 40 are located at a position not overlapping the reference chip 12, the stacked chip 22, or an other stacked chip 24, which is a connection destination, a stacked RDL 21 (not shown) is disposed on one surface of the reference chip 12 (surface opposite to the surface connected to the reference RDL 11), one surface of the stacked chip 22 (a surface on the stacked chip 22 of the stacked panel 20 to be stacked), and one surface of the other stacked chip 24 (a surface on the stacked chip 24 of the stacked panel 20 to be stacked).

The semiconductor module 1 and the semiconductor package 100 according to the third embodiment as described above achieve the following effects.

(7) The stacked panel 20 is connected to another stacked panel 20 or the reference panel 10 using the microbumps 40, the silicon through electrode 41, and the back surface RDL 27 electrically connected to the silicon through electrode 41. In addition, the stacked panel 20 is connected to another stacked panel 20 or the reference panel 10 using the microbumps 40, the silicon through electrode 41, and the stacked RDL 21 electrically connected to the silicon through electrode 41. Accordingly, even when the reference chip 12 and the stacked chip 22 are connected to each other using the microbumps 40, the area where the reference mold portion 14 and the stacked mold portion 23 overlap each other in the stacking direction can be reduced. Therefore, warpage of the semiconductor wafer 1 can be suppressed.

Although preferred embodiments of the semiconductor module and the semiconductor package of the present invention have been described above, the present invention is not limited to the above-described embodiments and can be modified as appropriate.

For example, in the above embodiment, the stacked chip 22 may be a different type of chip for each stacked panel 20. In the third embodiment, at least one of the stacked chips 22 may be a bumpless stacked chip.

In the above embodiment, the reference chip 12 may be a chip of the same type as the stacked chip 22. That is, the reference chip 12 may be a RAM.

In the third embodiment, pillars (not shown) may be used similarly to the first and second embodiments. As a result, since the areas of the reference mold portion 14 and the stacked mold portion 23 can be reduced, warpage of the semiconductor wafer 1 can be easily reduced.

### EXPLANATION OF REFERENCE NUMERALS

1 semiconductor module
10 reference panel
11 reference redistribution layer
12 reference chip
13, 26 pillar
14 reference mold portion
20 stacked panel
21 stacked redistribution layer
22, 24, 25 stacked chip
23 stacked mold portion
27 back surface redistribution layer
40 microbump
41 silicon through electrode
100 semiconductor package

1. A semiconductor module formed by integrally molding a plurality of chips, the semiconductor module comprising:
a reference panel comprising a plurality of reference chips arranged side by side, and a reference mold portion that fills at least spaces between the plurality of reference chips; and
at least one stacked panel comprising a plurality of stacked chips respectively stacked on the reference chips, and a stacked mold portion that fills at least spaces between the plurality of stacked chips, the stacked panel being stacked on one surface side of the reference panel,
each of the stacked chips being disposed so that a partial area thereof overlaps a partial area of a corresponding reference chip when viewed in a stacking direction and being disposed so as to overlap the reference mold portion, and
the reference chips being disposed so as to overlap the stacked mold portion.

2. The semiconductor module according to claim 1, wherein the stacked chips are stacked in a one-to-one correspondence with the reference chips in the stacking direction.

3. The semiconductor module according to claim 1,
wherein each of the reference chips is disposed toward one end of one diagonal line in a predetermined area of a rectangle in plan view including one of the reference chips and one of the stacked chips, in a direction intersecting the stacking direction, and
wherein each of the stacked chips is disposed toward the other end of the one diagonal line.

4. The semiconductor module according to claim 3,
wherein the at least one stacked panel comprises a plurality of stacked panels, and
wherein each of the stacked chips is disposed so as to partially overlap an other adjacent stacked chip when viewed in the staking direction and overlap the stacked mold portion of the other adjacent stacked chip.

5. The semiconductor module according to claim 4, wherein the stacked chips are stacked in a one-to-one correspondence with the other stacked chips in the stacking direction.

6. The semiconductor module according to claim 4,
wherein the other stacked chip is disposed toward one end of the other diagonal line, and
wherein still another stacked chip is disposed toward the other end of the other diagonal line.

7. The semiconductor module according to claim 3, wherein the stacked chips are different types of chips for each of the stacked panels.

8. The semiconductor module according to claim 3, wherein at least one of the stacked chips is a bumpless stacked chip.

9. The semiconductor module according to claim 3, wherein the stacked panel is connected to another stacked panel or the reference panel using microbumps.

10. The semiconductor module according to claim 1, wherein the reference chips are chips of a different type from the stacked chips.

11. A semiconductor package obtained by singulating the semiconductor module according to claim 1, the semiconductor package comprising one of the reference chips and corresponding stacked chip that are disposed so as to overlap each other as a set.
